(19) United States
(12) Patent Application Publication
(10) Pub. No.: US 2009/0065147 A1
(43) Pub. Date: Mar. 12, 2009

(54) Plasma processing apparatus

(76) Inventor: Osamu Morita, Hyogo-ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/920,343

(22) PCT Filed: Apr. 27, 2006
(86) PCT No.: PCT/JP2006/308874

§ 371 Date: Nov. 14, 2007

(30) Foreign Application Priority Data
May 17, 2005 (JP) 2005-143674

(51) Int. Cl. C23C 16/513; C23F 1/02

(52) U.S. Cl. 156/345.35; 118/723 R

(57) ABSTRACT

This invention is a plasma processing apparatus including: a processing vessel having: a plasma generating space in which a plasma is generated, and a processing space in which a substrate is placed and is subjected to a plasma process; a gas supplying plate arranged in the processing vessel so as to separate the plasma generating space and the processing space in the processing vessel; a process-gas supplying hole provided in the gas supplying plate for supplying a process gas into the processing vessel; a plurality of openings provided in the gas supplying plate for communicating the plasma generating space with the processing space; and a heat transfer member extending from a central region of the gas supplying plate to a peripheral region of the gas supplying plate, the heat transfer member having heat transfer rate higher than that of a material forming the gas supplying plate.

### FIELD OF THE INVENTION

The present invention relates to a plasma processing apparatus.

### BACKGROUND ART

Conventionally, a plasma processing apparatus in which a microwave is used has been used, for example, for a film forming process and/or processing an etching process. Furthermore, a background art has been suggested wherein in a plasma processing apparatus in which a microwave is used, a gas supplying plate called a shower plate is arranged horizontally in a processing vessel so as to separate an upper portion of a plasma generating space, and a lower portion of a processing space (Japanese Patent No. 3384795).

A plurality of gas supplying holes for supplying a process gas into the processing space and a plurality of openings for communicating the plasma generating space with the processing space are formed in the shower plate according to the background art. According to the plasma processing apparatus having this shower plate, it is possible to reduce damage to a substrate and to conduct a preferred plasma process at a high processing efficiency.

When a plasma CVD process, for example, is conducted by using the above-described apparatus, it is preferable that the temperature of the shower plate itself is controlled to be constant so as to prevent a reaction product from adhering to the shower plate.

However, during the plasma process, the temperature of the shower plate in particular at a central region becomes high due to heat caused by a generation of plasma. In other words, the temperature distribution becomes non-uniform in the whole plane of the shower plate.

Needless to say, a material itself of the shower plate can be a metal whose heat transfer rate is good, for example, aluminum. However, a plurality of openings for communicating the plasma generating space with the processing space are formed in the shower plate. The openings are formed for passing active species which are generated by plasma, and the section area of a shower plate section is designed to be as small as possible. Accordingly, a heat (transfer) resistance from the central region of the shower plate to the peripheral region of the shower plate is large, and it was difficult to make the in-plane temperature of the shower plate uniform and to maintain the temperature of the shower plate at a desirable temperature.

When the in-plane temperature of the shower plate becomes non-uniform or is not maintained at a desirable temperature, thermal stress increases, and deformation and/or distortion of the shower plate are caused. As a result, the shower plate itself needs to be changed frequently, and depending on the situation, even the uniformity of the plasma process can be hindered.

### SUMMARY OF THE INVENTION

The present invention is created by focusing the aforementioned problems in order to solve the problems effectively. An object of the present invention is to provide a plasma processing apparatus capable of maintaining a gas-supplying plate (a shower plate) at a desirable temperature, capable of improving a uniformity of an in-plane temperature of the gas supplying plate, and accordingly capable of suppressing an occurrence of deformation and/or distortion of the gas supplying plate.

The present invention is a plasma processing apparatus comprising: a processing vessel having a plasma generating space in which a process gas is made plasma, and a processing space in which a substrate is placed and is subjected to a plasma process; a gas supplying plate (so called a shower plate) arranged in the processing vessel so as to separate the plasma generating space and the processing space in the processing vessel; a process-gas supplying hole provided in the gas supplying plate for supplying the process gas into the processing space; a plurality of openings provided in the gas supplying plate for communicating the plasma generating space with the processing space; and a heat transfer member extending (in a stretching manner) from a central region of the gas supplying plate to a peripheral region of the gas supplying plate, the heat transfer member having heat transfer rate higher than that of a material forming the gas supplying plate.

According to the present invention, because the heat transfer member having a higher heat transfer rate than that of a material forming the gas supplying plate is extended (to be across) from the central region to the peripheral region of the gas supplying plate, a heat transference between the central region and the peripheral region of the gas supplying plate is improved remarkably in comparison with a conventional apparatus. As a result, the temperature of the gas supplying plate can be maintained at a desirable temperature, and the uniformity of the in-plane temperature distribution of the gas supplying plate is also improved. Consequently, an occurrence of deformation and distortion of the gas supplying plate during a process can be prevented.

Preferably, the heat transfer member is provided inside the gas supplying plate.

Additionally, it is preferable that when a region of the gas supplying plate facing a substrate has a lattice of vertical bars and lateral bars, (at least a portion of) the heat transfer member is provided inside a vertical bar or a lateral bar. In this case, it is preferable that (a portion of) a passage of the process gas in the gas supplying plate is also provided inside a vertical bar or a lateral bar.

In addition, the gas supplying plate is usually provided with another gas supplying hole for supplying a plasma generating gas (a gas for a plasma excitation) into the plasma generating space. Here, as described above, when a region of the gas supplying plate facing the substrate has a lattice of vertical bars and lateral bars, it is preferable that (a portion of) a passage of the plasma generating gas in the gas supplying plate is also provided inside a vertical bar or a lateral bar.

Moreover, it is preferable that the passage of the process gas and the passage of the plasma generating gas are arranged in an overlapped manner as seen in a vertical direction of the gas supplying plate. In this case, although the two passages are formed, the area of a plurality of openings which communicate the plasma generation space with the processing space is not affected. Furthermore, it is preferable that at least a portion of the heat transfer member is arranged between the passage of the process gas and the passage of the plasma generating gas.

Additionally, it is preferable that a passage of a heating medium for heat exchange against the heat transfer member at a peripheral region of the gas supplying plate is provided. In this case, it becomes easy to maintain the temperature of the whole of the gas supplying plate at a desirable temperature based on the heating medium which flows through the passage of the heating medium, and it becomes easy to control the temperature of the whole of the gas supplying plate uniformly.

A heat pipe, for example, can be taken as an example of a heat transfer member.

### BRIEF DESCRIPTION OF THE DRAWINGS

FIG. 1 is a schematic vertical section view showing a construction of a plasma processing apparatus according to one embodiment of the present invention;

FIG. 2 is a plan view showing a shower plate of the plasma processing apparatus shown in FIG. 1;

FIG. 3 is a longitudinal section view showing a lateral bar of the shower plate shown in FIG. 2;

FIG. 4 is a plan view for explaining the arrangement of vertical bars and lateral bars of the shower plate shown in FIG. 2;

FIG. 5 is a cross-sectional view by A-A line shown in FIG. 3;

FIG. 6 is a graph showing an in-plane temperature distribution of the shower plate according to this embodiment and that of a conventional shower plate;

FIG. 7 is a graph showing temperature changes of the conventional shower plate as time advances; and

FIG. 8 is a graph showing temperature changes of the shower plate according to this embodiment as time advances.

### DESCRIPTION OF THE PREFERRED EMBODIMENT

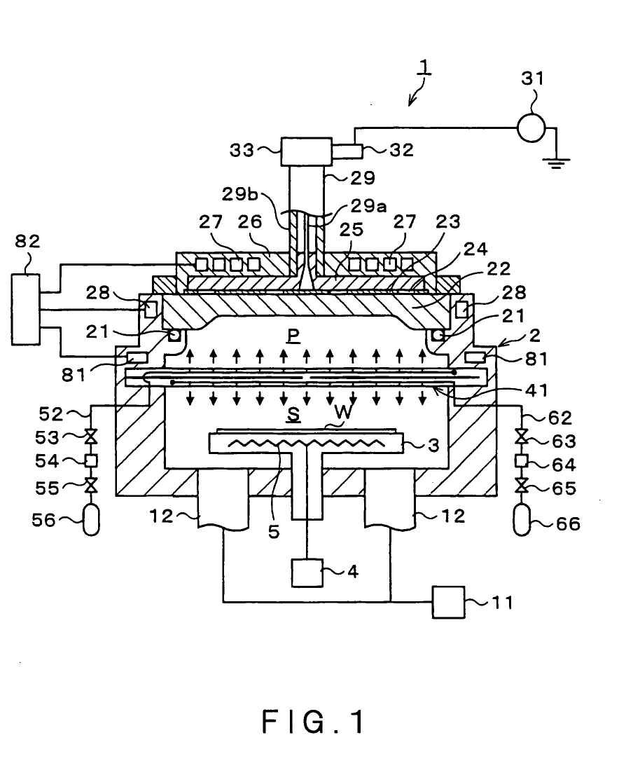

Hereinafter, a preferred embodiment of the present invention will be explained. FIG. 1 is a schematic vertical section view showing the construction of the plasma processing apparatus according to one embodiment of the present invention. The plasma processing apparatus 1 is provided with a cylindrical processing vessel 2 which has a bottom and whose upper part is open. The processing vessel 2 is made of, for example, aluminum and is grounded. At the bottom part of the processing vessels 2, a susceptor 3 is provided as a placing stage in order to place thereon, for example, a semiconductor wafer (to be referred to as a wafer) as a substrate. The susceptor 3 is made of, for example, aluminum. A heater 5 that generates heat by a supply of electricity from an external power source 4 is provided inside the susceptor 3. Consequently, the wafer W placed on the susceptor 3 can be heated to a predetermined temperature.

A gas-discharging pipe 12 for discharging an atmosphere inside the processing vessel 2 by means of a gas-discharging unit 11 such as a vacuum pump and the like is provided at the bottom part of the processing vessel 2.

A transmissive window 22 made of, for example, a quart member which is a dielectric is provided at the upper opening of the processing vessel 2 via a sealing material 21 such as an O-ring for securing air-tightness. With regard to the transmissive window 22 according to this embodiment, its planer form is circular. Other dielectric materials, for example, the ceramics such as AL₂O₃, AlN and so on can be used instead of a quartz member.

A plane antenna member, for example, a disc-like radial line slot antenna 23 is provided on an upper surface of the transmissive window 22. The radial line slot antenna 23 is comprised of a material which has conductive property, for example, a thin copper disk which has been plated or coated with Ag, Au or the like. A plurality of slits 24 are formed in the radial line slot antenna 23 to be aligned, for example, in a spiral pattern or in a concentric circle pattern.

A slow wave plate 25 for shortening a wavelength of a microwave which will be described later is arranged on the upper surface of the radial line slot antenna 23. The slow-wave plate 25 is covered with a cover 26 having conductive property. A circular ring-shape passage 27 for a heating medium is provided in the cover 26. By means of the heating medium which flows through this passage 27, the cover 26 and the transmissive window 22 are adapted to be maintained at a predetermined temperature. In addition, in the side wall of the processing vessel 2 in a vicinity of the outer-periphery edge of the transmissive window 22, another circular ring-shape passage 28 for the heating medium is formed.

A coaxial wave guide tube 29 is connected to the cover 26. This coaxial wave guide tube 29 is composed of an inner conductor 29a and an outer tube 29b. The inner conductor 29a is connected to the radial line slot antenna 23. An end part of the inner conductor 29a at a side of the radial line slot antenna 23 has a cone shape and therefore, is adapted to be able to transfer a microwave efficiently to the radial line slot antenna 23.

A microwave of, for example 2.45 GHZ, which is generated in a microwave supplying unit 31, is emitted to the transmissive window 22 via a rectangular wave guide tube 32, a mode transducer 33, the coaxial wave guide tube 29, the slow-wave plate 25 and the radial line slot antenna 23. By means of microwave energy on this occasion, an electric field is formed on an under surface of the transmissive window 22, and a gas in a plasma generating space P is changed into plasma.

A shower plate 41 as a gas-supplying plate is arranged horizontally in the processing vessel 2. By this arrangement, the inside of the processing vessel 2 is separated into an upper portion as the plasma generating space P and a lower portion as the processing space S.

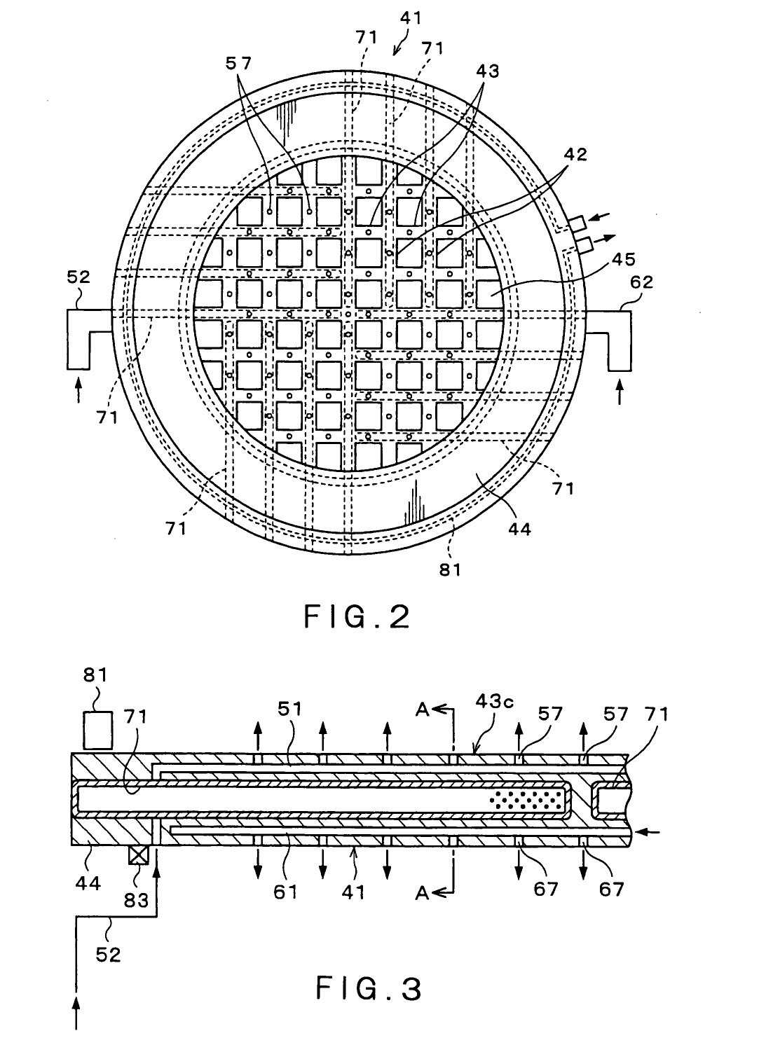

As shown in FIG. 2, the shower plate 41 is substantial disk-shaped, and a region facing the wafer W placed on the susceptor 3 has such a shape that a plurality of vertical bars 42 and a plurality of lateral bars 43 are arranged like a lattice. A circular ring member 44 is provided at its outside. A material of each of these members is aluminum. In addition, by means of the vertical bars 42 and the lateral bars 43, a plurality of quadrangle opening 45 are created. Each opening 45 communicates the plasma generating space P with the processing space s.

As shown in FIG. 3, a gas passage 51 through which a gas for a plasma excitation flows is formed inside of each vertical bar 42 and each lateral bar 43 on a side of the plasma generating space P. This gas passage 51, as shown in FIG. 1, leads to a gas-supplying source 56 for a plasma excitation gas via a gas-supplying pipe 52, a bulb 53, a massflow controller 54 and a valve 55. Moreover, as shown in FIG. 3, a plurality of gas-supplying holes 57 are formed in the vertical bars 42 and the lateral bars 43 on the side of the plasma generating space P so as to supply the gas for the plasma excitation, which flows through the gas passage 51, uniformly into the plasma generating space P.

On the other hand, as shown in FIG. 3, a passage of a process gas 61 through which a process gas flows is formed on a side of the processing space S inside of each vertical bar 42 and each lateral bar 43. This passage of the process gas 61, as shown in FIG. 1, lead to a process-gas supplying source 66 via a process-gas supplying pipe 62, a bulb 63, a massflow controller 64 and a valve 65. Moreover, as shown in FIG. 3, a plurality of process-gas supplying holes 67 are formed on the side of the processing space S in the vertical bars 42 and in the lateral bars 43 so as to supply the process gas, which flows through the passage of the process gas 61, uniformly into the processing space S.

A heat pipe 71 is provided inside of each vertical bar 42 and each lateral bar 43. This heat pipe 71 has a hollow cylinder shape, and inside of it, water is filled as a heating medium. Needless to say, a heat pipe whose inside is filled with another liquid used in various kinds of heat pipes can be used according to a target temperature range for controlling the temperature of the shower plate 41. The heat transfer rate of the heat pipe 71 is extremely higher than that of an aluminum which is a component material of the shower plate 41.

The heat pipe 71 is provided inside the vertical bar 42 and the lateral bar 43 in such a manner that the heat pipe 71 extends (across) from a central region to a peripheral region of the shower plate 41. Hereinafter, the arrangement will be described in details.

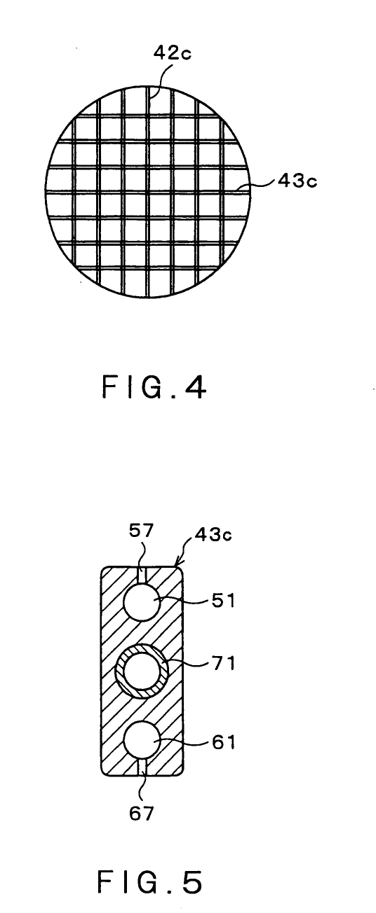

As shown in FIG. 2 and FIG. 4, with regard to the vertical bar 42c that passes through a center of the shower plate 41, a heat pipe 71, 71, whose length corresponds to about a radius of the shower plate 41, is inserted therein from each of the outer ends thereof so as to face each other. Similarly, with regard to the lateral bar 43c that passes through the center of the shower plate 41, a heat pipe 71, 71 whose length corresponds to about the radius of the shower plate 41 is inserted therein from each of the outer ends thereof so as to face each other.

Furthermore, out of the four regions of the shower plate 41 divided into four by these vertical bar 42c and lateral bar 43c, with regard to so called first quadrant (the upper-right quarter circular part of the shower plate 41 in FIG. 2 and FIG. 4) and so called third quadrant (the lower-left quarter circular part of the shower plate 41 in FIG. 2 and FIG. 4), a heat pipe 71 is inserted into the inside of each vertical bar 42 from the outer end thereof, and with regard to so called second quadrant (the upper-left quarter circular part of the shower plate 41 in FIG. 2 and FIG. 4) and so called fourth quadrant (the lower-right quarter circular part of the shower plate 41 in FIG. 2 and FIG. 4), a heat pipe 71 is inserted into the inside of each lateral bar 43 from the outer end thereof. The outer ends of the heat pipes 71 reach to the outer end (edge) of the shower plate 41 respectively. In this manner, the heat pipes 71 are arranged almost uniformly in an area of a lattice-shape of the shower plate 41.

Furthermore, with regard to a part where the gas passage 51 and the passage of the process gas 61 overlap each other in the vertical bar 42 and the lateral bar 43, as shown in FIG. 3 and FIG. 5, the heat pipe 71 is located between these passages in such a manner that the heat pipe 71 is overlapped in a vertical direction with the gas passage 51 and the passage of the process gas 61.

Additionally, as shown in FIG. 1, a circular ring part 44 of the shower plate 41 is supported by a side wall of the processing vessel 2. Additionally, a circular ring-shape passage of a heating medium 81 is provided on an upper portion of the circular ring part 44 of the shower plate 41 inside the side wall of the processing vessel 2. A heat exchange is conducted between the heating medium which flows through this passage for the heating medium 81 and the heat pipe 71 (the peripheral part of the heat pipe 71).

Here, the heating medium which flows through the passage of the heating medium 81 and the heating medium which flows through the passages of the heating medium 27, 28 as described above are supplied from the same supplying source of a heating medium 82 in this embodiment. However, when a temperature of a target area to be controlled is different, each independent supplying source of a heating medium (such as a chiller and the like) can be used respectively.

Additionally, as shown in FIG. 3, a circular ring-shape heater 83 may be provided on an under surface of an inner side of the circular ring part 44. Especially, as described above, in a conventional shower plate in which a heat (transfer) resistance from a central region to a peripheral region in the shower plate is large, uniformity of an in-plane temperature of a shower plate is poor. Thus, it is very preferable that a heater 83 is provided in order to make the temperature of the peripheral region of the shower plate be close to the temperature of the central region. Herein, note that in the shower plate 41 according to this embodiment, the heater 83 may not be provided because uniformity in temperature is remarkably improved.

The plasma processing apparatus 1 in this embodiment is composed as described above. When a plasma film-forming process is conducted to a wafer W placed on the susceptor 3 by the plasma processing apparatus 1, a gas for a plasma excitation, for example, an argon gas is supplied into the plasma generating space P from the gas supplying holes 57 of the shower plate 41. A microwave supplying unit 31 is operated in this condition. Then, an electric field is generated under a lower surface of the transmissive window 22 and the gas for the plasma excitation is changed into plasma, and the plasma flows into the processing space S through the openings 45 of the shower plate 41. Furthermore, when a process gas for a film forming process is supplied into the processing space S from the process-gas supplying holes 67 on the under surface of the shower plate 41, the process gas is dissociated by the plasma, and the film-forming process is conducted to the wafer W by the activated species which are generated on the occasion.

During this plasma process, the temperature of the central region of the shower plate 41 is risen by the heat caused by the plasma. However, in this embodiment, because the heat pipes 71 are provided in such a manner that the heat pipes 71 extend from the central region to the peripheral region (including the circular ring-shape part 44 in this embodiment) in the shower plate 41, the heat of the central region of the shower plate 41 is rapidly transferred to the peripheral region (the circular ring-shape part 44) of the shower plate 41. Accordingly, the temperature of the shower plate 41 is made uniform as a whole.

Besides, in this embodiment, the heat pipes 71 are arranged almost uniformly inside the vertical bars 42 and the lateral bars 43 which are arranged in a lattice manner. Consequently, the temperature uniformity of the whole of the shower plate 41 is improved much better.

Additionally, in this embodiment, because the passage of the heating medium 81 is provided above the upper part of the circular ring part 44 and a heat exchange is conducted between the end parts of the heat pipes 71 and the heating medium in the passage of the heating medium 81, this heating medium serves as a kind of a constant-temperature source, and accordingly, the shower plate 41 can be maintained at a desirable temperature.

As described above, in this embodiment, because the heat pipes 71 are adopted as a heat transfer member, it is easy to operate, and also an external energy source such as a power supply is not needed.

In short, according to a temperature control by means of a heating medium, the heat of the heating medium is provided to the shower plate 41 through the heat pipes 71 while the plasma processing apparatus is being idled (in the condition where the plasma is not being generated), and the heat of the shower plate 41 is provided to the heating medium through the heat pipes 71 while the plasma process is being conducted. That is to say, in each condition, the shower plate 41 can be maintained at a constant temperature. On the other hand, according to a temperature control not by means of a heating medium but by means of, for example, a conventional heater, a shower plate can be controlled at a constant temperature by means of the heater during an idling step, but the temperature of the shower plate rises more during a plasma process. Consequently, a mechanism to cool the shower plate as well as a power supply for a heater and its controller are needed, and therefore, the apparatus becomes complicated and the control of the apparatus becomes difficult.

Furthermore, in the vertical bars 42 and the lateral bars 43 in which the heat pipes 71 are provided, as shown in FIG. 5, the gas passage 51, the heat pipe 71 and the passage of the process gas 61 are arranged in an overlapped manner in a vertical direction, and therefore, the size of each opening 45 is not affected.

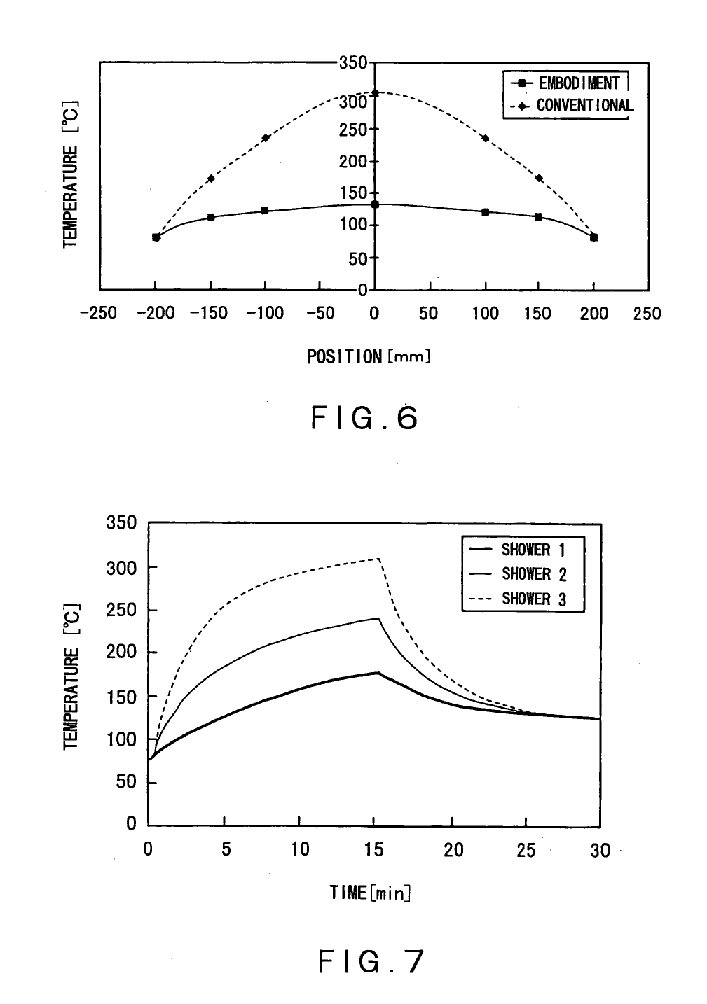

Next, with regards to the shower plate 41 adopted in the plasma apparatus 1 according to this embodiment and a conventional shower plate which does not have a heat transfer member, uniformity of an in-plane temperature is compared. The actual results of temperature measurements are shown in FIG. 6.

In the graph of FIG. 6, a distance from the center of the shower plate to the outer end is expressed on a horizontal axis, and a measured temperature is expressed on a vertical line. The process conditions of the plasma process were the followings: the pressure in the processing vessel 2 was 666.5 Pa (500 mTorr): the power of a microwave was 3 KW; the flow rate of an argon gas for plasma excitation was 1700 sccm; the temperature of the heating medium flowing through the passage of the heating medium 81 was 80° C.; the temperature of the heater 83 is 80° C.

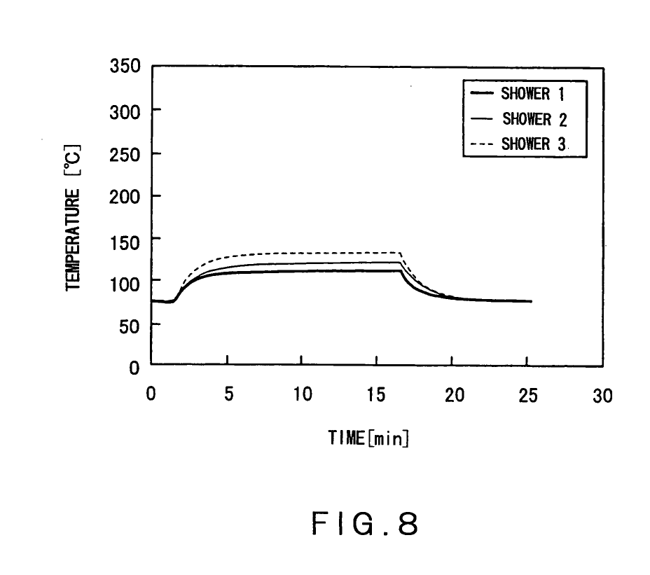

In addition, FIG. 7 shows the temperature change as time passes after the plasma (generating) ON with regard to three positions of a conventional shower plate which does not have a heat transfer member. On the other hand, FIG. 8 shows the temperature change as time passes after the plasma (generating) ON with regard to the three positions of the shower plate 41 adopted in the plasma apparatus 1 according to this embodiment. The plasma (generating) was turned off after fifteen minutes has passed. Here, with regard to the three positions, in both of FIG. 7, and FIG. 8, “shower 1” means an edge (positioned at 150 mm from the center), “shower 2” means the middle (positioned at 100 mm from the center), and “shower 3” means the center (positioned at 0 mm from the center).

Additionally, with regard to the conditions of the plasma process under which these temperatures were measured, the pressure in the processing vessel 2 was 666.5 Pa (500 mTorr), the power of a microwave was 3 kW; the flow rate of an argon gas for plasma excitation was 1700 sccm.

As known from these results, it has been found that, in the shower plate 41 adopted in the plasma apparatus 1 according to this embodiment, the temperature is maintained at a desirable temperature and also the in-plane temperature is almost uniform. Accordingly, it has been found that a thermal stress upon the shower plate 41 is restrained much more than that upon a conventional shower plate and that its deformation and distortion become remarkably less.

Besides, it has been found that the plasma apparatus according to this embodiment is superior to a conventional one with regard to a temperature response as well as uniformity of an in-plane temperature. That is to say, in the conventional plasma apparatus (FIG. 7), the temperature keeps rising for fifteen minutes after the plasma is turned on (till the plasma is turned off), but in the plasma apparatus (FIG. 8) according to this embodiment, the temperature already becomes stable five minutes after the plasma is turned on. This is the same with the situation after the plasma is turned off.

Therefore, according to this embodiment, changes of the conditions during the process are fewer and the stability is improved compared to that of the conventional apparatus. In short, for example, when a plurality of substrates are processed in succession, there is no difference of the process results between the first substrate right after staring the process and the following substrates processed after the temperature becomes stable. Additionally, even when one substrate needs to be processed for a long time, the temperature changes of the shower plate are less, and, moreover, the condition of adsorption of a gas to the shower plate and desorption thereof from the shower plate does not change, so that a more stable process is enabled. Furthermore, because a temperature response is good as described above, the time till starting the actual process can be shortened than before.

Incidentally, although the embodiment described above is explained as a plasma processing apparatus which makes use of a microwave, the present invention is not limited thereto, and the present invention can be applied to other plasma processing apparatuses which make use of other plasma sources.

1. A plasma processing apparatus comprising:
a processing vessel having a plasma generating space in which a plasma is generated, and a processing space in which a substrate is placed and is subjected to a plasma process,
a gas supplying plate arranged in the processing vessel so as to separate the plasma generating space and the processing space in the processing vessel,
a process-gas supplying hole provided in the gas supplying plate for supplying a process gas into the processing vessel,
a plurality of openings provided in the gas supplying plate for providing communication between the plasma generating space and the processing space, and
a heat transfer member extending from a central region of the gas supplying plate to a peripheral region of the gas supplying plate, the heat transfer member having a heat transfer rate higher than that of a material forming the gas supplying plate.

2. A plasma processing apparatus according to claim 1, wherein
the heat transfer member is provided inside the gas supplying plate.

3. A plasma processing apparatus according to claim 1, wherein
a region of the gas supplying plate facing the substrate has a lattice of vertical bars and lateral bars, and
at least a portion of the heat transfer member is provided inside a vertical bar or a lateral bar.

4. A plasma processing apparatus according to claim 3, wherein
the gas supplying plate has a circular ring portion around the lattice, and
the circular ring portion is supported by a side wall of the processing vessel.

5. A plasma processing apparatus according to claim 4, wherein
a passage of a heating medium is provided in the side wall of the processing vessel, and
a heating medium that flows through the passage of a heating medium and the heat transfer member are adapted to conduct a heat exchange.

6. A plasma processing apparatus according to claim 3, wherein
a region of the gas supplying plate facing the substrate is divided into four sectors,
at least a portion of the heat transfer member is provided inside the vertical bar in two sectors, and
at least a portion of the heat transfer member is provided inside the lateral bar in the other two sectors.

7. A plasma processing apparatus according to claim 3, wherein
a portion of a passage of the process gas in the gas supplying plate is provided inside a vertical bar or a lateral bar.

8. A plasma processing apparatus according to claim 1, wherein
the gas supplying plate is provided with another gas supplying hole for supplying a plasma generating gas into the plasma generating space.

9. A plasma processing apparatus according to claim 3, wherein
the gas supplying plate is provided with another gas supplying hole for supplying a plasma generating gas into the plasma generating space, and
a portion of a passage of the plasma generating gas in the gas supplying plate is provided inside a vertical bar or a lateral bar.

10. A plasma processing apparatus according to claim 8, wherein
the passage of the process gas and the passage of the plasma generating gas are arranged in an overlapped manner as seen in a vertical direction of the gas supplying plate.

11. A plasma processing apparatus according to claim 8, wherein
a portion of the heat transfer member is arranged between the passage of the process gas and the passage of the plasma generating gas.

12. A plasma processing apparatus according to claim 1, further comprising
a passage of a heating medium for heat exchange against the heat transfer member at a peripheral region of the gas supplying plate.

13. A plasma processing apparatus according to claim 1, wherein
the heat transfer member is a heat pipe.
